(19) United States
(12) Patent Application Publication
(10) Pub. No.: US 2002/0063607 A1
(43) Pub. Date: May 30, 2002

(54) Multi-phase LC oscillator

(75) Inventors: Johan David Van Der Tang, Eindhoven (NL); Wolfdietrich Georg Kasperkovitz, Waalre (AT); Pepijn Willebrord Justinus Van De Ven, Eindhoven (NL)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 09/998,034

(22) Filed: Nov. 29, 2001

(30) Foreign Application Priority Data
Nov. 30, 2000 (EP) 00204264.6

(51) Int. Cl. H03B 5/18

(52) U.S. Cl. 331/100

(57) ABSTRACT

A multiphase LC oscillator is proposed which belongs to the so-called class, which delivers correct-by-construction I/Q signals.

Unlike state of the art I/Q LC oscillators, the proposed invention oscillates at the point where the quality factor of the resonator is maximum.

Hence the new multiphase LC oscillator provides also maximum carrier to noise ratio correct by construction given a certain resonator. This is realized by implementing the V/I converters which couple the N LC oscillators, with an exact 180/N-degree phase shift.

The invention relates to a multi-phase LC oscillator.

In many modern integrated transceivers architectures, in-phase (I) and quadrature (Q) signals are needed in the signal processing part.

An example is the zero-IF architecture in which the incoming RF input signal is converted directly to a baseband signal. When the carrier-to-noise ratio (CNR) requirements, given a certain power budget, of an IVQ oscillator are stringent, use of I/Q LC oscillators can be required. Phase noise of LC oscillators is better than RC oscillators given a limited power budget, since energy can be stored in the resonator of the LC oscillator and only the losses in de resonator and active device have to be compensated periodically.

From the international patent application WO96/33552 a LC oscillator is known which is coupled to one or more additional LC oscillators in order to increase the stability of an oscillator. The oscillator is a single-phase oscillator, which does not operate at optimum point if the amplifier has a parasitic phase shift.

An object of the invention is to extend the class of correct by construction I/Q LC oscillator that in addition provides optimum CNR performance correct by construction.

To this end a multi-phase LC oscillator according to the invention comprises the features of claim 1.

Quadrature signals are obtained when this multi-phase oscillator has an even number of stages.

It is to be noticed here that further several integrated I/Q LC oscillator architectures are known in the art. These oscillators do belong to the so-called class of correct-by construction oscillators, since they are based on two identical/symmetrical sections. However, these state of the art architectures do not oscillate at zero phase shift of the resonator, which leads to sub-optimal CNR performance of these I/Q oscillators.

Embodiments of the invention are described in the depended claims.

These and other aspects of the invention will be apparent from and elucidated with reference to examples described here and after. Herein shows:

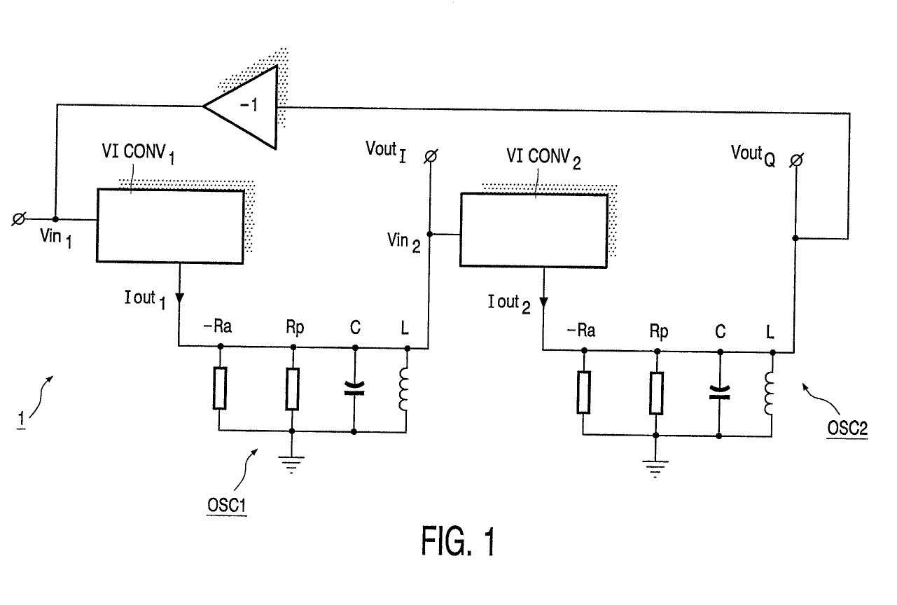

FIG. 1 block-schematically an example of a multiphase LC oscillator according to the invention,

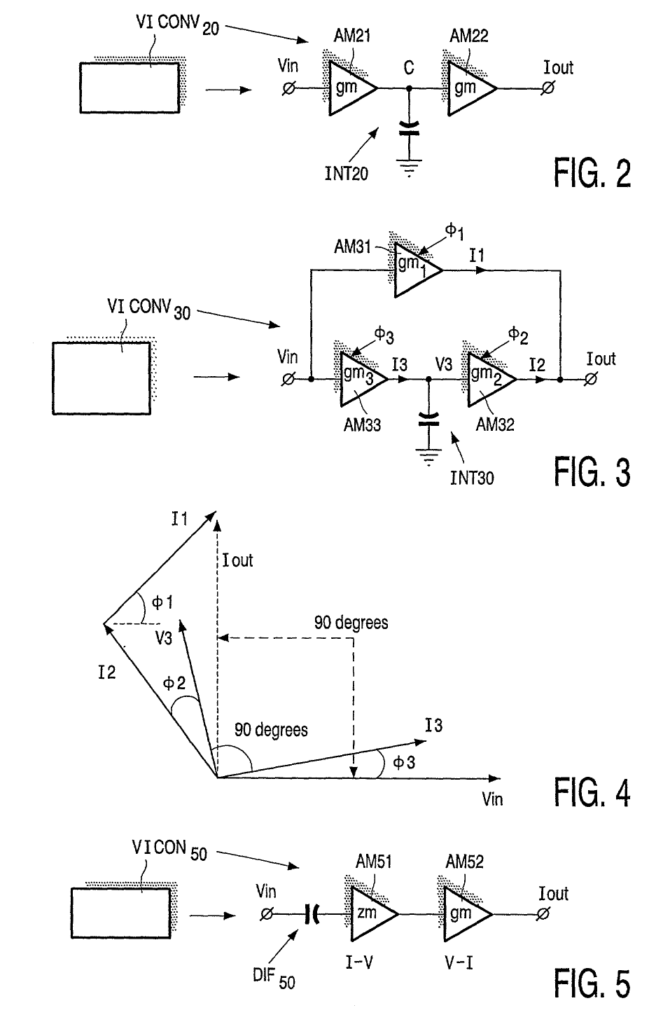

FIG. 2 block-schematically an example of V/I converter according to the invention,

FIG. 3 block-schematically a second example of a V/I converter with compensation according to the invention,

FIG. 4 a phase plot of the example of FIG. 3, and

FIG. 5 a block-schematically an third example of a V/I converter according to the invention.

FIG. 1 shows block-schematically an example of a multiphase LC oscillator 1 according to the invention. At a first input Vᵢₙ₁ the multiphase LC oscillator receives an input signal. This input is coupled to a first voltage-to-current converter VICONV1. At an output the voltage-to-current converter supplies an output current Iₒᵤₜ₁ to a first LC oscillator OSC1. In this example the LC oscillator comprises an inductance L, a capacitor C, a resistance Rp and a parasitic resistance—Ra.

The output of the LC oscillator is coupled to an input Vᵢₙ₂ of a second voltage-to-current converter VICONV2. This input Vᵢₙ₂ is at the same time a first output Vₒᵤₜ₁ of the multiphase LC oscillator 1.

The input Vᵢₙ₂ supplies the output signal of the oscillator OSC1 to the converter VICONV2.

The converter supplies as output signal the current Iₒᵤₜ₂ to a second oscillator OSC2. This second oscillator comprises in this example the same elements as the oscillator OSC1.

The output of the oscillator OSC2 is coupled to the second output V_{outQ} of the multiphase LC oscillator 1.

The output V_{outQ} is also coupled as feedback signal to the first input Vᵢₙ₁ of the multiphase LC oscillator via an inverter.

The two LC oscillators OSC1 and OSC2 are coupled with the V/I converters, which implement the necessary 90-degree phase shift. This phase shift can be positive or negative. This exact 90-degree phase-shift ensures that the oscillator(s) operates at a maximum slope of the resonator phase-characteristic. Also only one oscillation point is available which is important for robustness.

Tuning can be realized in several ways. The LC oscillator OSC1 and OSC2 can be tunable, for example by means of varactors.

Alternatively, tuning can be implemented by varying the phase shift of the V/I converters VICONV1 and VICONV2. In that case the phase shift of each V/I converter is 90 degrees +/− the phase shift of the resonator which corresponds to the wanted frequency. Tuning is, in this way performed, around the optimum operating point of the resonator.

In a practical implementation, oscillator OSC1 and oscillator OSC2 will have some parasitic phase shift. In that case the V/I converters must provide (in this special case of a 2-stagew multi-phase oscillator: I/Q oscillator) 90 degrees shift minus the parasitic phase shift for optimum operation.

The exact 90 degrees phase-shift can be introduced in several ways:

implementing an integrator within the V/I converter

implementing a differentiator within the V/I converter

In general: a network that provides 90 degrees phase-shift. This network or circuit may be adjustable to ensure 90 degrees phase-shift over the complete tuning range of the oscillator.

FIG. 2 shows block-schematically an example of V/I converter VICONV20 according to the invention. In this example an integrator INT20 implements the 90 degrees phase-shift. The amplifiers AM21 and AM22 are in this example supposed to be ideal, so having no phase shift.

FIG. 3 block-schematically a second example of a V/I converter VICONV30 with compensation according to the invention. In this example the amplifiers AM33 and AM32 can have some (parasitic) phase shift which has to be compensated by a third amplifier AM31 which is in this example coupled parallel to the other two amplifiers. The phase shift of each amplifier is respectively φ1, φ2, and φ3. In FIG. 4 the phase plot of the different phase shift is shown. The integrator INT30 implements a 90 degrees phase-shift. If (due to the implementation) the amplifiers AM33 and AM32 have some (parasitic) phase shift, the amplifier AM31 is set to compensate for this and make the total phase shift 90 degrees. At the same time the amplifier AM31 can be used for tuning around the maximum phase slope point.

FIG. 4 shows a phase plot of the example of the V/I converter VICON30 of FIG. 3. This phase plot shows how an exact 90 degrees can be achieved taking into account the phase-shift of the transconductances (φ1, φ2, and φ3) due to implementation, parasitic effects etc.

FIG. 5 shows block-schematically an third example of a V/I converter VICON50 according to the invention. In this example the conversion of 90 degrees is implemented as a differentiation by a differentiator DIF50 to obtain the 90 degrees phase shift and two amplifiers AM51 and AM52 whereby the amplifier AM51 accomplishes a current to voltage conversion and the amplifier AM52 accomplishes a voltage to current conversion. This combined with the differentiation of the differentator DIF50 accomplishes an overall voltage to current conversion. The amplifier AM51 has in this example its input coupled with virtual ground.

It will be noticed by the man skilled in the art that also in this example as in the example shown in FIG. 3 also if necessary here a kind of compensation can be achieved.

Further it will be clear that the invention is not limited to the aforementioned examples and that instead of the shown multiphase LC oscillator as a second stage oscillator it is also possible to obtain higher order multiphase LC oscillators with the same invention. In case the multi phase LC oscillator has an even number of stages quadrature signals can be obtained.

1. Multiphase LC oscillator comprising N units whereby N is at least 2, and each unit performs a phase shift of 180°/N of an incoming signal, whereby each unit comprises a VI converter part with a phase shift 180°/N and an LC oscillation part, and the multiphase LC oscillator supplies at least two outputs signal with a phase difference.

2. Multiphase LC oscillator as claimed in claim 1, characterized in that each unit comprises control means to adjust the phase shift to obtain the required phase shift of 180°/N.
Multiphase LC oscillator as claimed in claim 2, characterized in that a VI converter of the unit comprises amplifiers in series with a compensation amplifier parallel.

3. V/I converter for use in a multiphase LC oscillator according to claim 1, characterized in that V/I converter comprises compensation means to compensate for a phase shift.

4. Method to obtain multiphase signals with phase differences 180 degrees/N whereby N is at least 2, having the steps of receiving an incoming signal, performing a phase shift of 180 degrees/N and supplying signals with a phase difference.
